(19) United States
(12) Patent Application Publication
(10) Pub. No.: US 2015/0268989 A1
(43) Pub. Date: Sep. 24, 2015

(54) Methods and Systems for Extending the Object Store of an Application Virtual Machine

(71) Applicant: SanDisk Enterprise IP LLC, Milpitas, CA (US)

(72) Inventors: John Busch, Cupertino, CA (US); Brian O'Krafka, Austin, TX (US); Patrick Chiu, Cupertino, CA (US); Yachun Miao, Hangzhou (CN)

(21) Appl. No.: 14/339,072

(22) Filed: Jul. 23, 2014

Related U.S. Application Data
(60) Provisional application No. 61/969,705, filed on Mar. 24, 2014.

(51) Int. Cl. G06F 9/48; G06F 12/12; G06F 9/50; G06F 12/02; G11C 7/10

(52) U.S. Cl. CPC G06F 9/4856; G06F 12/0246; G06F 12/0253; G11C 7/1072; G06F 9/5016; G06F 12/121; G06F 2212/7205; G06F 2212/69

(57) ABSTRACT

The embodiments described herein include methods and systems for improving the performance of application virtual machines by extending an object store corresponding to the application virtual machine. The method includes identifying a subset of migratable objects from a plurality of objects associated with the application virtual machine, where the subset of migratable objects includes one or more objects and the plurality of objects are stored in the object store comprising a portion of the memory allocated for the application virtual machine. The method also includes selecting a respective object from the subset of migratable objects to be migrated from the object store to a persistent datastore, where the persistent datastore is distinct from the object store. The method further includes causing the respective object to be migrated from the object store to the persistent datastore.

### RELATED APPLICATIONS

This application claims priority to U.S. Provisional Patent Application No. 61/969,705, filed Mar. 24, 2014, which is hereby incorporated by reference in its entirety.

### TECHNICAL FIELD

The disclosed embodiments relate generally to application virtual machines, and in particular, to extending the object store (e.g., the heap) of an application virtual machine (e.g., a Java virtual machine).

### BACKGROUND

Generally, an instance of a Java virtual machine (“JVM”) executes a single application or program. The JVM includes a plurality of runtime data areas for the application including a method area and a heap. Both the method area and the heap are shared between all threads of the application. The heap is allocated a predefined amount of high-speed, high-cost memory (e.g., DRAM) for storing objects instantiated by the application. However, if the program requires more heap space than can be made available, the JVM throws an OutOfMemoryError.

Currently, virtual memory is used to extend the heap by utilizing a large swap file. However, this solution has very poor performance due to page granularity and swapping algorithms.

### SUMMARY

The disclosed method and system improves the performance of application virtual machines by extending the object store (e.g., the heap) of the application virtual machine using lower-cost non-volatile memory (e.g., flash memory). In turn, this helps the application access large amounts of data without the virtual machine throwing an OutOfMemoryError and without the application suffering poor performance due to paging the heap, while providing reduced cost and higher data capacity relative to expanding DRAM. Furthermore, the object store is extended in manner that is maximally transparent to the application or program.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate the more pertinent features of the present disclosure and are therefore not to be considered limiting, for the description may admit to other effective features.

FIGS. 1A-1B are block diagrams illustrating implementations of an application virtual machine in accordance with some embodiments.

FIG. 2A is a block diagram illustrating an implementation of a memory manager in accordance with some embodiments.

FIG. 2B is a block diagram illustrating an implementation of an electronic device executing the application virtual machine in accordance with some embodiments.

FIG. 3 is a block diagram illustrating a memory hierarchy in accordance with some embodiments.

FIGS. 4A-4B are block diagrams illustrating implementations of data structures associated with the application virtual machine in accordance with some embodiments.

FIG. 5 illustrates block diagrams of data structures associated with an implementation of a garbage collection process for the application virtual machine in accordance with some embodiments.

FIGS. 6A-6C illustrate a flowchart representation of a method of managing objects associated with an application virtual machine in accordance with some embodiments.

FIGS. 7A-7B illustrate a flowchart representation of a method of managing objects associated with an application virtual machine in accordance with some embodiments.

In accordance with common practice the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

The various embodiments described herein include methods, devices and/or systems that improve the reliability and performance of an application virtual machine (sometimes also called a process virtual machine) such as a Java virtual machine (“JVM”). Some embodiments include methods, devices and/or systems for extending the object store (e.g., the heap) of the application virtual machine into high-capacity, cost effective persistent datastore.

Some embodiments include a method of managing objects associated with an application virtual machine. In some embodiments, the method is performed by an application virtual machine that is executed or hosted by an electronic device (e.g., a client device or server system) with one or more processors and memory that is operatively coupled to a memory manager that is configured to manage a persistent datastore. The method includes identifying a subset of migratable objects from a plurality of objects associated with the application virtual machine, where the subset of migratable objects includes one or more objects and the plurality of objects are stored in an object store comprising a portion of the memory allocated for the application virtual machine. The method also includes selecting a respective object from the subset of migratable objects to be migrated from the object store to a persistent datastore operatively coupled to the electronic device, where the persistent datastore is distinct from the memory associated with the electronic device. The method further includes causing the respective object to be migrated from the object store to the persistent datastore.

Some embodiments include a method of managing objects associated with an application virtual machine. In some embodiments, the method is performed by an application virtual machine that is executed or hosted by an electronic device (e.g., a client device or server system) with one or more processors and memory that is operatively coupled to a memory manager that is configured to manage a persistent datastore. The method includes identifying a subset of migratable objects from a plurality of objects associated with the application virtual machine, where the subset of migratable objects includes one or more objects and the plurality of objects are stored in an object store comprising a portion of memory allocated for the application virtual machine. The method also includes: detecting a modification (or creation) of a first object in the subset of migratable objects; and, in response to detecting the modification (or creation), causing the modified (or created) first object to be migrated to a persistent datastore operatively coupled to the electronic device, where the persistent datastore is distinct from the memory associated with the electronic device. The method further includes: selecting a second object from the subset of migratable objects to be migrated from the object store to the persistent datastore. In accordance with a determination that the selected second object is distinct from the first object, the method includes causing the selected second object to be migrated to the persistent datastore. In accordance with a determination that the selected second object is the first object, the method includes forgoing migration of the selected second object.

Some embodiments include an electronic system or device, comprising: one or more processors; and memory storing one or more programs to be executed by the one or more processors, the one or more programs comprising instructions for performing or controlling performance of any of the methods described herein. Some embodiments include a non-transitory computer readable storage medium, storing one or more programs for execution by one or more processors of an electronic system or device, the one or more programs including instructions for performing any of the methods described herein. Some embodiments include an electronic system or device comprising: means for performing the operations of any of the methods described herein. In some embodiments, an application virtual machine is executed or hosted by the electronic system or device.

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known methods, components, and circuits have not been described in exhaustive detail so as not to unnecessarily obscure more pertinent aspects of the embodiments described herein.

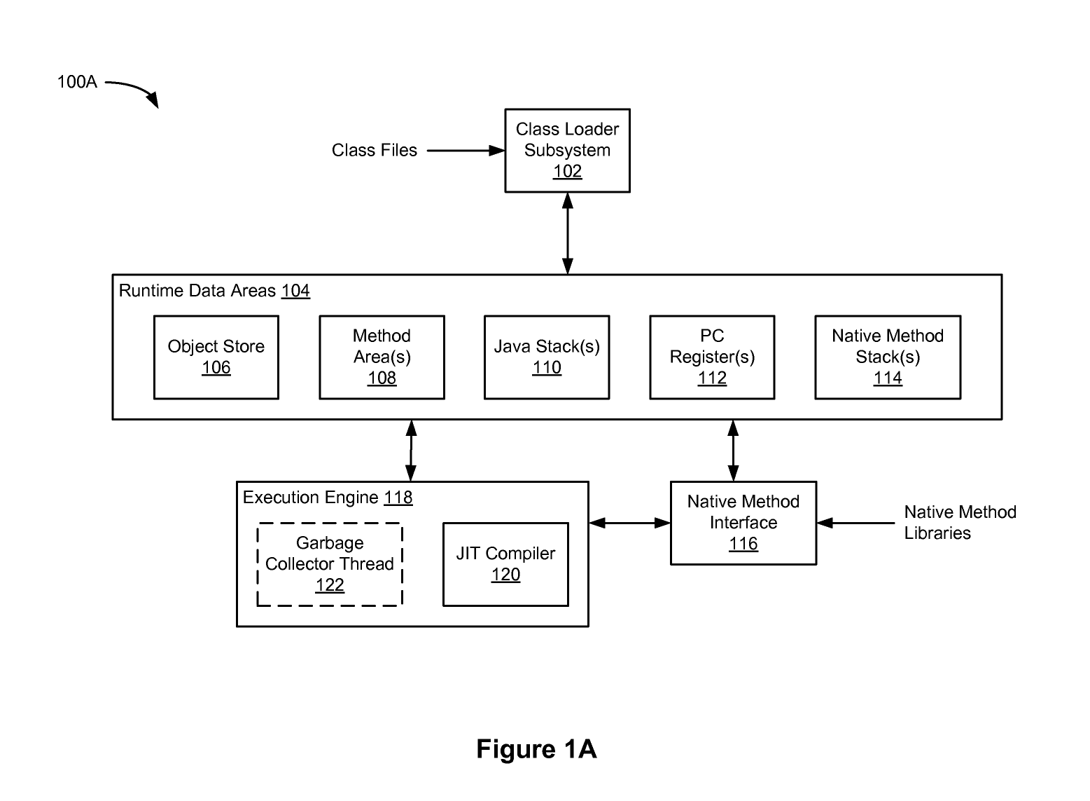

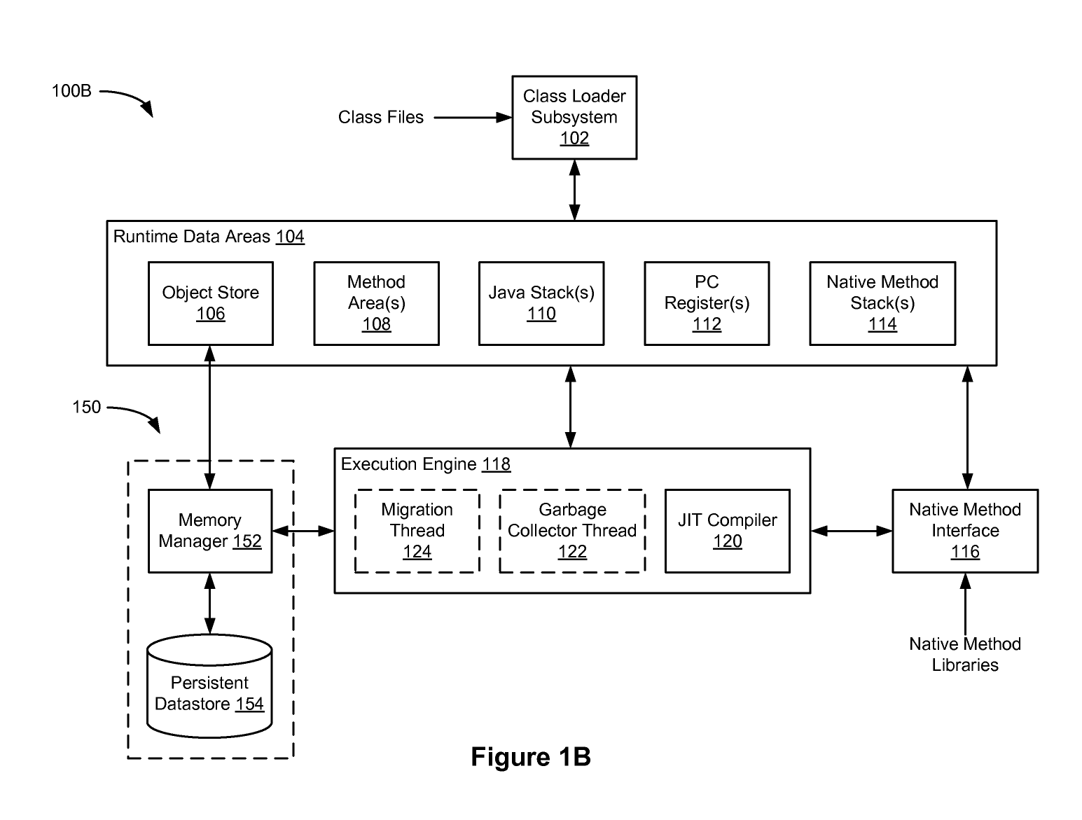

FIG. 1A is a block diagram illustrating an implementation of an application virtual machine 100A in accordance with some embodiments. For example, application virtual machine 100A illustrates a representative instance of a virtual machine for a respective application or program. For ease of discussion, application virtual machine 100A is described as a Java virtual machine (“JVM”). However, one of ordinary skill in the art will appreciate how the described embodiments and methods disclosed herein may also apply to any of a plurality of similar application virtual machine implementations written in any of a plurality of interpretive languages (e.g., Smalltalk, Java, Lisp, Scala, Ruby, etc.).

A runtime instance of a Java virtual machine has a clear mission: to run one Java application or program. When a Java application starts, a runtime instance is created, and, when the Java application completes, the instance is stopped. As an example, if a user starts three Java applications at the same time, on the same computer, three Java virtual machine instances will be created, where the three Java applications run inside a respective Java virtual machine instance.

In some embodiments, a Java virtual machine instance starts running its solitary application by invoking the main( ) method of some initial class. Any class with such a main( ) method can be used as the starting point for a Java application. The main( ) method of an application's initial class serves as the starting point for that application's initial thread. The initial thread can spawn other threads. In some embodiments, threads come in two flavors: daemon and non-daemon. A daemon thread is ordinarily a thread used by the virtual machine itself for background processes such as a thread that performs garbage collection. However, the initial thread of an application—the one that begins at main( )—is a non-daemon thread. A Java application continues to execute (the virtual machine instance continues to live) as long as any non-daemon threads are still running. When all non-daemon threads of a Java application terminate, the virtual machine instance terminates.

FIG. 1A illustrates a block diagram of Java virtual machine 100A that includes major subsystems and memory areas in accordance with some embodiments. Java virtual machine 100A includes a class loader subsystem 102 and an execution engine 118. Class loader subsystem 102 is a mechanism for loading types (i.e., classes and interfaces) given fully qualified names. Execution engine 118 is a mechanism responsible for executing the instructions contained in the methods of loaded classes.

In some embodiments, execution engine 118 includes just-in-time (“JIT”) compiler 120 and garbage collector thread 122. JIT compiler 120 is configured to compile bytecode into native machine code at runtime and execute the native machine code. In some embodiments, garbage collector thread 122 is a daemon thread that is configured to scan objects in object store 106 and mark unreferenced objects (i.e., objects that are not referenced or pointed to by other objects) for garbage collection and reclamation.

When Java virtual machine 100A runs an application or program, memory is required to store bytecode and other information Java virtual machine 100A extracts from loaded class files, objects the application instantiates, parameters to methods, return values, local variables, intermediate results of computations, and the like. Java virtual machine 100A organizes the memory needed to execute the application into a plurality of runtime data areas 104. In some embodiments, some of runtime data areas 104 are shared among all threads of an application and others are unique to a respective thread. Each instance of the Java virtual machine has a method area 108 and an object store 106 (sometimes also called a “heap”). Method area 108 and object store 106 are shared by all threads running inside Java virtual machine 100A. When Java virtual machine 100A loads a class file, it parses information about a type from the binary data contained in the class file. Java virtual machine 100A places this type information into method area 108, and, as the application runs, Java virtual machine 1 OOA places all objects the application instantiates into object store 106.

In some embodiments, as each new thread comes into existence, the new thread is allocated its own respective PC register 112 (e.g., a program counter) and Java stack 110. If the thread is executing a Java method (not a native method), the value of the respective PC register indicates the next instruction to execute, and the thread's respective Java stack stores the state of Java (i.e., not native) method invocations for the thread. The state of a Java method invocation includes its local variables, the parameters with which it was invoked, its return value (if any), and intermediate calculations. In comparison, the state of native method invocations is stored in an implementation-dependent way in native method stack(s) 114, as well as possibly in registers or other implementation-dependent memory areas.

In some embodiments, Java stack(s) 110 are composed of stack frames (or frames). A stack frame contains the state of one Java method invocation. When a thread invokes a method, the Java virtual machine pushes a new frame onto that thread's Java stack. When the method completes, the Java virtual machine pops and discards the frame for that method. In some embodiments, Java virtual machine 100A has no registers to hold intermediate data values. Instead, the instruction set uses Java stack(s) 110 for storage of intermediate data values. In some embodiments, native method interface 116 is configured to allow a Java program to call a function in a C or C++ program (i.e., a native method) or to allow a C or C++ program to call a function in a Java program. For example, native methods may be called from native method libraries using native method interface 116.

FIG. 1B illustrates a block diagram of modified application virtual machine 100B that is operatively coupled to persistence environment 150 in accordance with some embodiments. In some embodiments, application virtual machine 100B is a modified implementation of application virtual machine 100A that includes one or more migration threads, including representative migration thread 124. Application virtual machine 100B is similar to application virtual machine 100A, described above in FIG. 1A. As such, similar reference numbers will not be discussed again for sake of brevity.

In some embodiments, migration thread 124 is a daemon thread that is preloaded or embedded in modified application virtual machine 100B. Migration thread 124 is configured to manage a background migration/eviction process that causes objects to migrate from object store 106 into persistence environment 150 according to a set of migration and/or eviction polices. In some embodiments, the set of migration and eviction polices are predetermined, or, in some other embodiments, the set of migration and/or eviction policies provided by the application or program being run in application virtual machine 100B. In some embodiments, migration thread 124 is also configured to retrieve objects from persistence environment 150 when the application requires or references a migrated object.

In some embodiments, persistence environment 150 includes memory manager 152 and persistent datastore 154. Memory manager 152 is configured to manage persistent datastore 154 via a set of CRUD (Create, Read, Update, and Delete) operations. Persistent datastore 154 includes non-volatile memory such as one or more magnetic disk storage devices, optical disk storage devices, flash memory devices, or other non-volatile solid state storage devices.

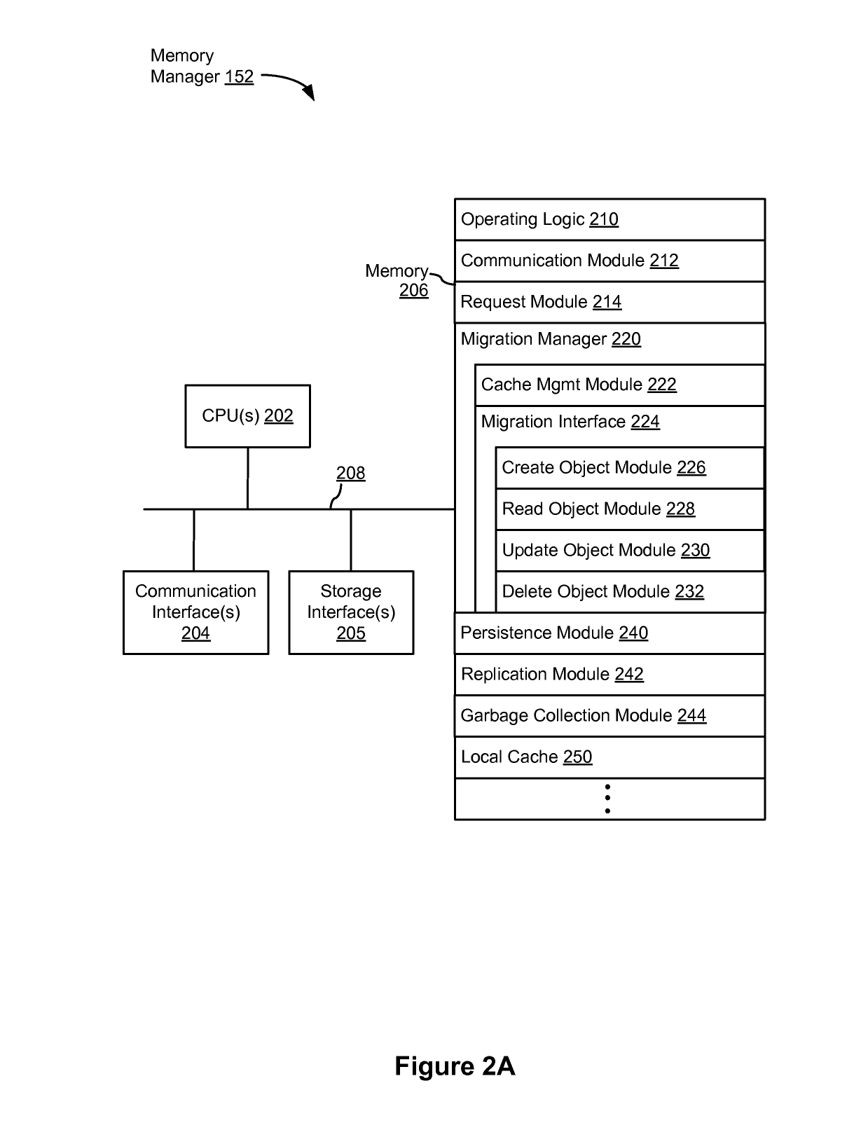

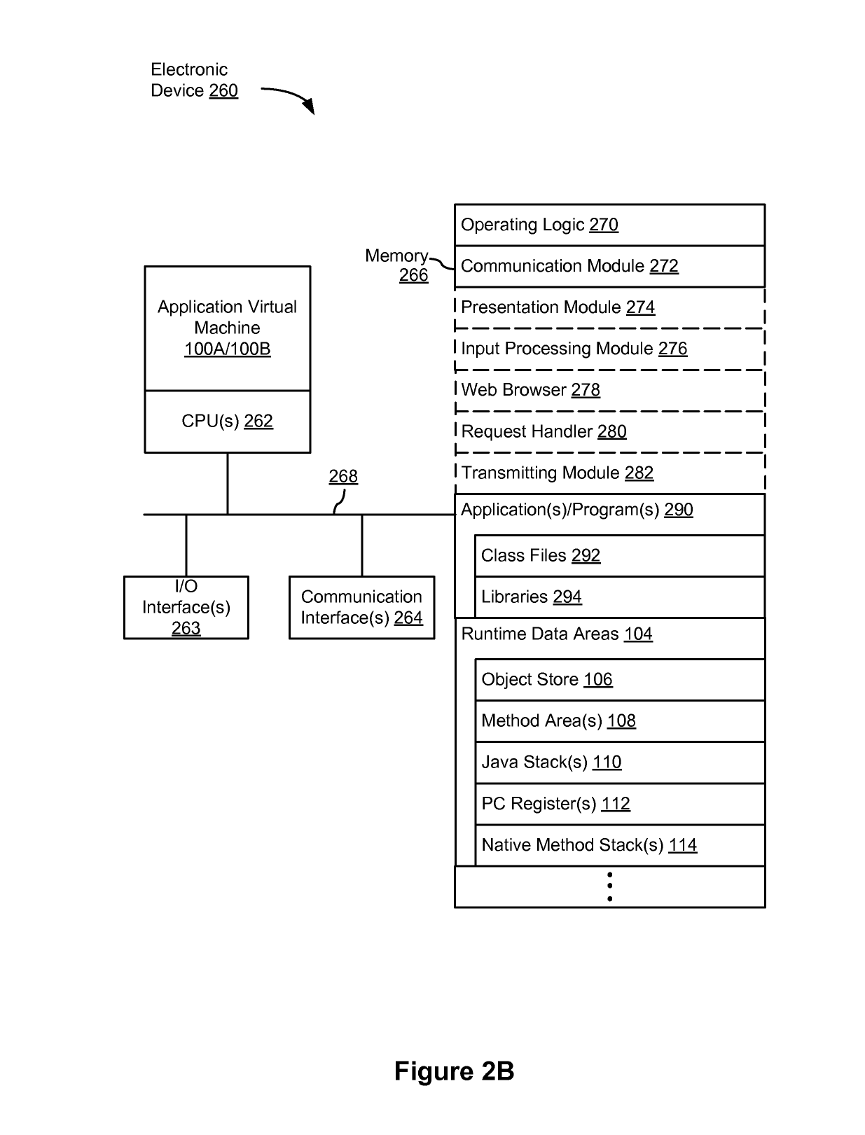

FIG. 2A is a block diagram illustrating an implementation of memory manager 152 in accordance with some embodiments. Memory manager 152 typically includes one or more processors (also sometimes called CPUs or processing units or microprocessors or microcontrollers) 202 for executing modules, programs and/or instructions stored in memory 206 and thereby performing processing operations, memory 206, one or more communication interfaces 264 to other computing devices (e.g., memory manager 150), one or more storage interfaces 205 to storage devices (e.g., persistent datastore 154), and one or more communication buses 208 for interconnecting these components. Communication buses 208 optionally include circuitry (sometimes called a chipset) that interconnects and controls communications between system components. In some embodiments, memory manager 152 is operatively coupled with other computing devices, such as electronic device 260, by communication buses 208 and one or more communication interfaces 204. In some embodiments, memory manager 152 is operatively coupled with storage devices, such as persistent datastore 154, by communication buses 208 and one or more storage interfaces 205. Memory 206 includes one or more semiconductor memory devices such as high-speed random access memory (e.g., DRAM, SRAM, DDR RAM or other random access solid state memory devices), and may include non-volatile memory (e.g., such as one or more magnetic disk storage devices, one or more optical disk storage devices, one or more flash memory devices, one or more three-dimensional (3D) memory devices, or other non-volatile solid state storage devices). Memory 206 optionally includes one or more storage devices remotely located from processor(s) 202. Memory 206, or alternately the non-volatile memory device(s) within memory 206, comprises a non-transitory computer readable storage medium. In some embodiments, memory 206, or the computer readable storage medium of memory 206 stores the following programs, modules, and data structures, or a subset thereof:
operating logic 210 includes procedures for handling various basic system services and for performing hardware dependent tasks;
communications module 212 for communicating with other computer systems or computer components (e.g., electronic device 260, FIG. 2B) via one or more communication interfaces 204;
request module 214 for receiving, responding to, and handling requests from electronic device 260 (e.g., JNI (Java native interface) get and put calls from migration thread 124);
migration manager 220 for performing CRUD (Create, Read, Update, and Delete) operations to migrate objects between object store 106 and persistent datastore 154, including but not limited to:
   cache management module for managing and evicting objects stored in local cache 250;
   migration interface 224 for processing requests received from migration thread 124, including but not limited to:
      create object module 226 for inserting an object into persistent datastore 154 in response to a request (e.g., a JNI put call) from migration thread 124 to migrate a selected object;
      read object module 228 for retrieving an object from persistent datastore 154 in response to a request (e.g., a JNI get call) from migration thread 124;
      update object module 230 for updating the value of an object in persistent datastore 154; and
      delete object module 232 for deleting an object in persistent datastore 154 in response to a request from garbage collector thread 122 to delete an object marked for garbage collection;
persistence module 240 for persisting objects between instances of an application virtual machine;
optionally, replication module 242 for replicating, between nodes of a distributed storage system, one or more objects stored in persistent datastore 154;
garbage collection module 244 for performing a garbage collection process on the objects migrated to persistent datastore 154 in parallel with the garbage collection process performed by garbage collector thread 122; and
local cache 250 (e.g., implemented in DRAM) for storing migrated objects prior to storage in persistent datastore 154 and for caching migrated objects for read access.

Each of the above identified elements may be stored in one or more of the previously mentioned memory devices, and corresponds to a set of instructions for performing a function described above. The above identified modules or programs (i.e., sets of instructions) need not be implemented as separate software programs, procedures or modules, and thus various subsets of these modules may be combined or otherwise re-arranged in various embodiments. In some embodiments, memory 206 may store a subset of the modules and data structures identified above. Furthermore, memory 206 may store additional modules and data structures not described above.

FIG. 2B is a block diagram illustrating an implementation of electronic device 260 in accordance with some embodiments. Electronic device 260 may be any suitable computing device such as a computer, a laptop computer, a tablet device, a netbook, an internet kiosk, a personal digital assistant, a mobile phone, a smart phone, a wearable computing device, a set-top box, a gaming device, a server system (e.g., an application server or a web server), or any other computing device. Electronic device 260 typically includes one or more processors (also sometimes called CPUs or processing units or microprocessors or microcontrollers) 262 for executing modules, programs and/or instructions stored in memory 266 and thereby performing processing operations, memory 266, one or more input/output interfaces 263 to one or more input/output devices (e.g., one or more speakers, one or more visual displays, a keyboard, a mouse, a voice-command input unit or microphone, a touch screen display, a touch-sensitive input pad, a gesture capturing camera, and/or other input buttons or controls), one or more communication interfaces 264 to other computing devices (e.g., memory manager 152), and one or more communication buses 268 for interconnecting these components. Communication buses 268 optionally include circuitry (sometimes called a chipset) that interconnects and controls communications between system components. In some embodiments, electronic device 260 is operatively coupled with memory manager 152 by communication buses 268 and one or more communication interfaces 264. Memory 266 includes one or more semiconductor memory devices such as high-speed random access memory (e.g., DRAM, SRAM, DDR RAM or other random access solid state memory devices), and may include non-volatile memory (e.g., such as one or more magnetic disk storage devices, one or more optical disk storage devices, one or more flash memory devices, one or more three-dimensional (3D) memory devices, or other non-volatile solid state storage devices). Memory 266 optionally includes one or more storage devices remotely located from processor(s) 262. Memory 266, or alternately the non-volatile memory device(s) within memory 266, comprises a non-transitory computer readable storage medium.

In some embodiments, when electronic device 260 is a client device (e.g., a mobile phone, laptop computer, desktop computer, tablet computer, wearable computing device, or other computing device) that is operatively coupled with a server system (e.g., an application server) via one or more networks (i.e., wired or wireless), memory 266, or the computer readable storage medium of memory 266 stores the following programs, modules, and data structures, or a subset or superset thereof:
operating logic 270 includes procedures for handling various basic system services and for performing hardware dependent tasks;
communications module 272 that is used for communicating with other computer systems (e.g., memory manager 152, a server system, etc.) or computer components over the one or more networks via one or more communication interfaces 268;
presentation module 274 for enabling presentation of information (e.g., a user interface, webpage, or an application, audio and/or video content, text, etc.) at client device 104 via one or more output devices (e.g., displays, speakers, etc.) associated with one or more input/output interfaces 263;
input processing module 276 for detecting one or more user inputs or interactions from one of the one or more input devices (e.g., keyboard, mouse, microphone, touch screen display, etc.) associated with one or more input/output interfaces 263 and interpreting the detected input or interaction;
web browser 278 for viewing and accessing webpages; and
one or more applications/programs 290 for execution by application virtual machine 100A/100B, including but not limited to:
   class files 292 for one or more applications/programs 290; and
   libraries 294 for one or more applications/programs 290; and
runtime data areas 104 corresponding to application virtual machine 100A/100B, including but not limited to:
   object store 106 storing objects instantiated by methods of application virtual machine 100A/100B;
   method area(s) 108 storing parsed type information from loaded class files 292;
   Java stack(s) 110 storing stack frames in separate a separate Java stack for each thread of application virtual machine 100A/100B;
   PC register(s) 112 storing a program counter in a separate register for each thread of application virtual machine 100A/100B; and
   native method stack(s) 114 storing the state of native method invocations.

In some embodiments, when electronic device 260 is a server system (e.g., an application server) that is operatively coupled with one or more client devices (e.g., mobile phones, laptop computers, desktop computers, tablet computers, wearable computing devices, or other computing devices) via one or more networks (i.e., wired or wireless), memory 266, or the computer readable storage medium of memory 266 stores the following programs, modules, and data structures, or a subset or superset thereof:
operating logic 270 includes procedures for handling various basic system services and for performing hardware dependent tasks;
communications module 272 that is used for communicating with other computer systems (e.g., memory manager 152, one or more client devices, etc.) or computer components over the one or more networks via one or more communication interfaces 268;
request handler 280 for receiving and responding to requests from one or more client devices;
transmitting module 282 for transmitting information to one or more client devices; and
one or more applications/programs 290 for execution by application virtual machine 100A/100B, including but not limited to:
   class files 292 for one or more applications/programs 290; and
   libraries 294 for one or more applications/programs 290; and
runtime data areas 104 corresponding to application virtual machine 100A/100B, including but not limited to:
   object store 106 storing objects instantiated by methods of application virtual machine 100A/100B;
   method area(s) 108 storing parsed type information from loaded class files 292;
   Java stack(s) 110 storing stack frames in separate a separate Java stack for each thread of application virtual machine 100A/100B;
   PC register(s) 112 storing a program counter in a separate register for each thread of application virtual machine 100A/100B; and
   native method stack(s) 114 storing the state of native method invocations.

In some embodiments, electronic device 260 (e.g., a client device or server system) executes or hosts application virtual machine 100A/100B within which a respective application/program of one or more applications/programs 290 is executed. In some embodiments, a portion of memory 266 (e.g., DRAM) is allocated for application virtual machine 100A/100B to form its runtime data areas 104. In some embodiments, application virtual machine 100A/100B loads class files 292 or libraries 294 associated with the respective application/program 290.

In one example, when electronic device 260 is a client device, the respective application/program is an applet executed within application virtual machine 100A/100B, and application virtual machine 100A/100B is a client application executed or hosted by the client device. In this example, the respective application/program is typically executed in a process separate from the process used to execute web browser 278. In another example, when electronic device 260 is a server system, the respective application/program is a servlet executed within application virtual machine 100A/100B, and application virtual machine 100A/100B is a server application executed or hosted by the server system.

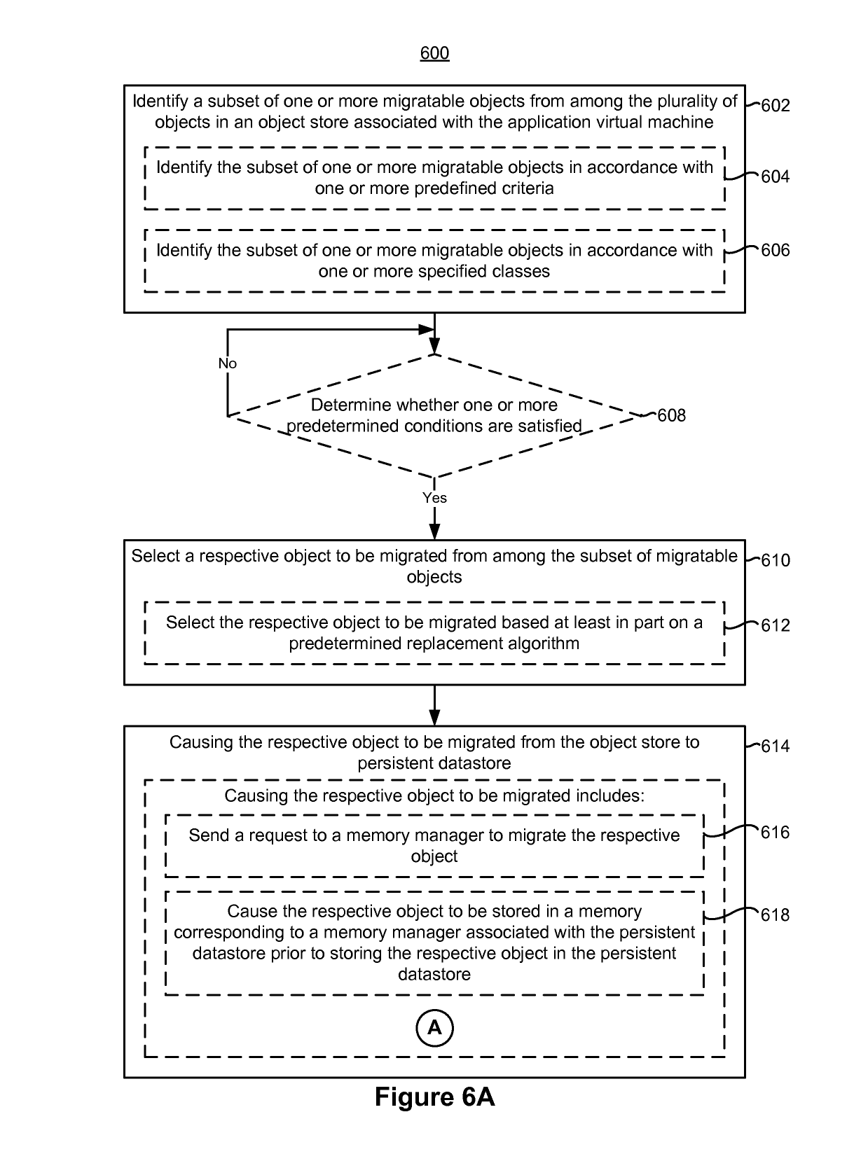

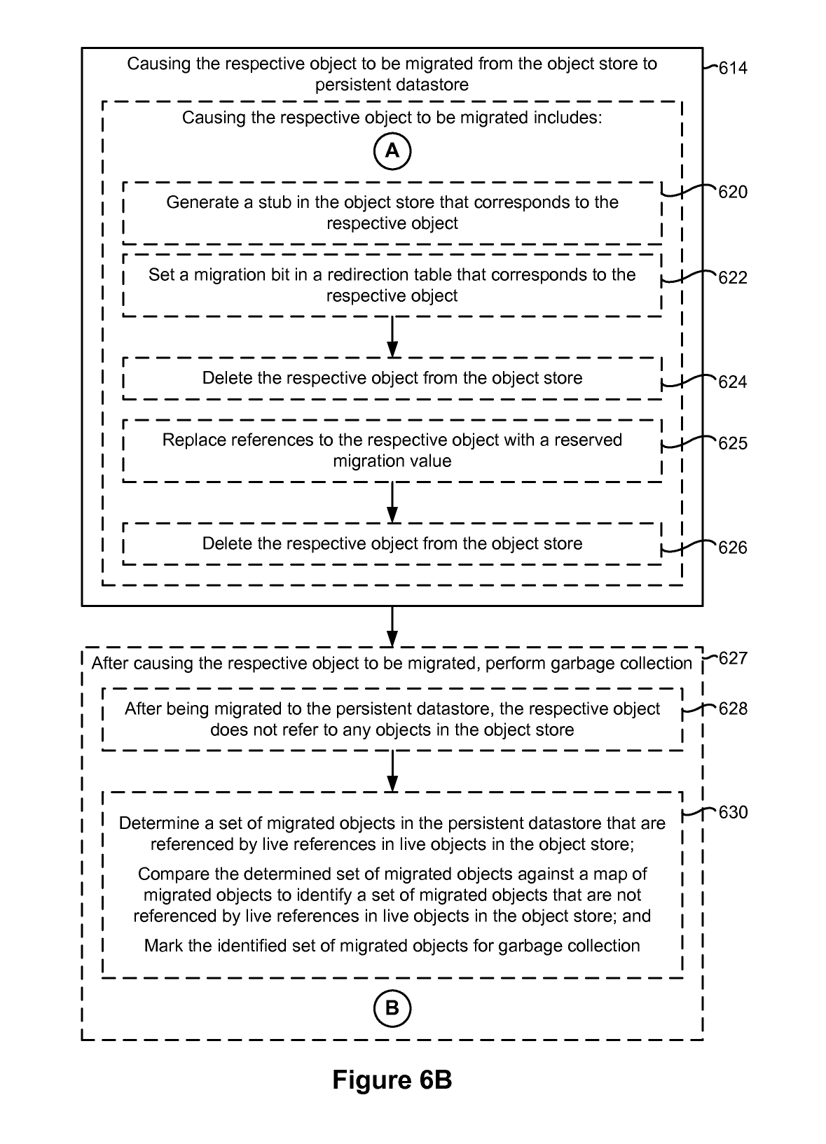

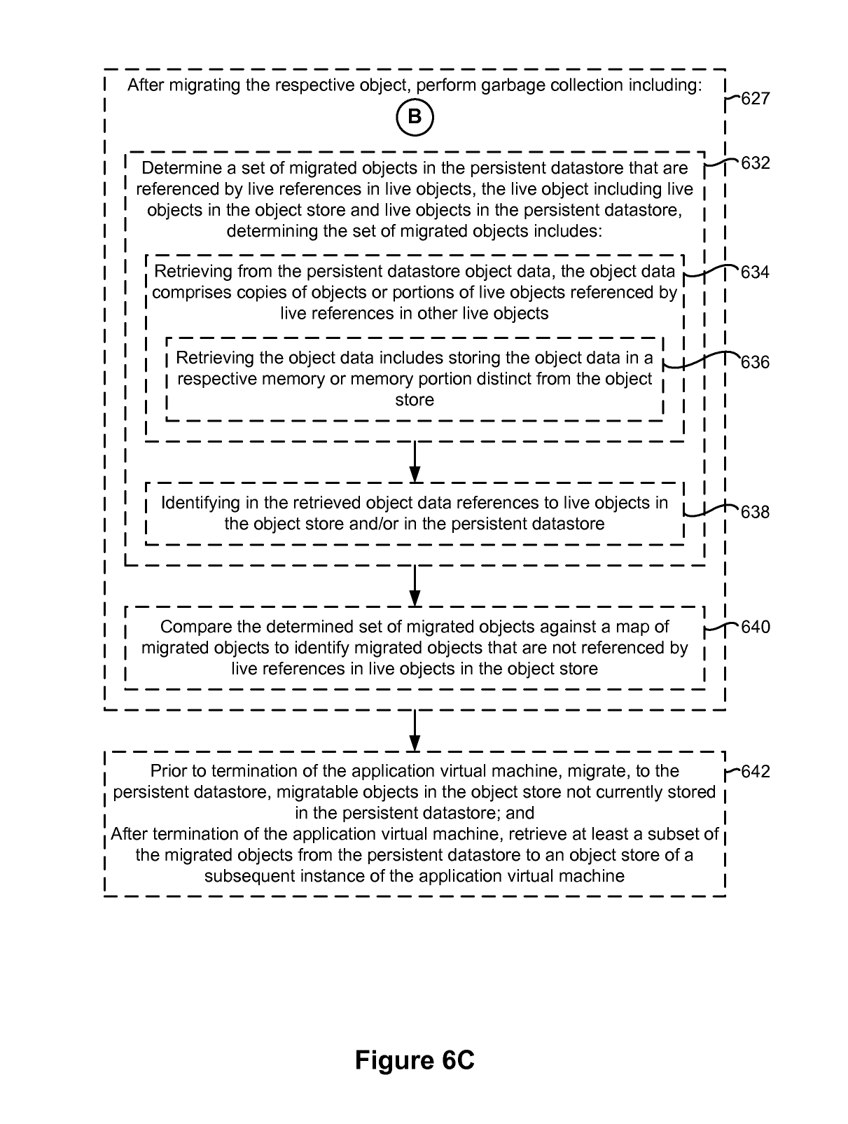

Each of the above identified elements may be stored in one or more of the previously mentioned memory devices, and corresponds to a set of instructions for performing a function described above. The above identified modules or programs (i.e., sets of instructions) need not be implemented as separate software programs, procedures or modules, and thus various subsets of these modules may be combined or otherwise re-arranged in various embodiments. In some embodiments, memory 266 may store a subset of the modules and data structures identified above. Furthermore, memory 266 may store additional modules and data structures not described above. In some embodiments, the programs, modules, and data structures stored in memory 266, or the computer readable storage medium of memory 266, provide instructions for implementing respective operations in the methods described below with reference to FIGS. 6A-6C and/or 7A-7B.

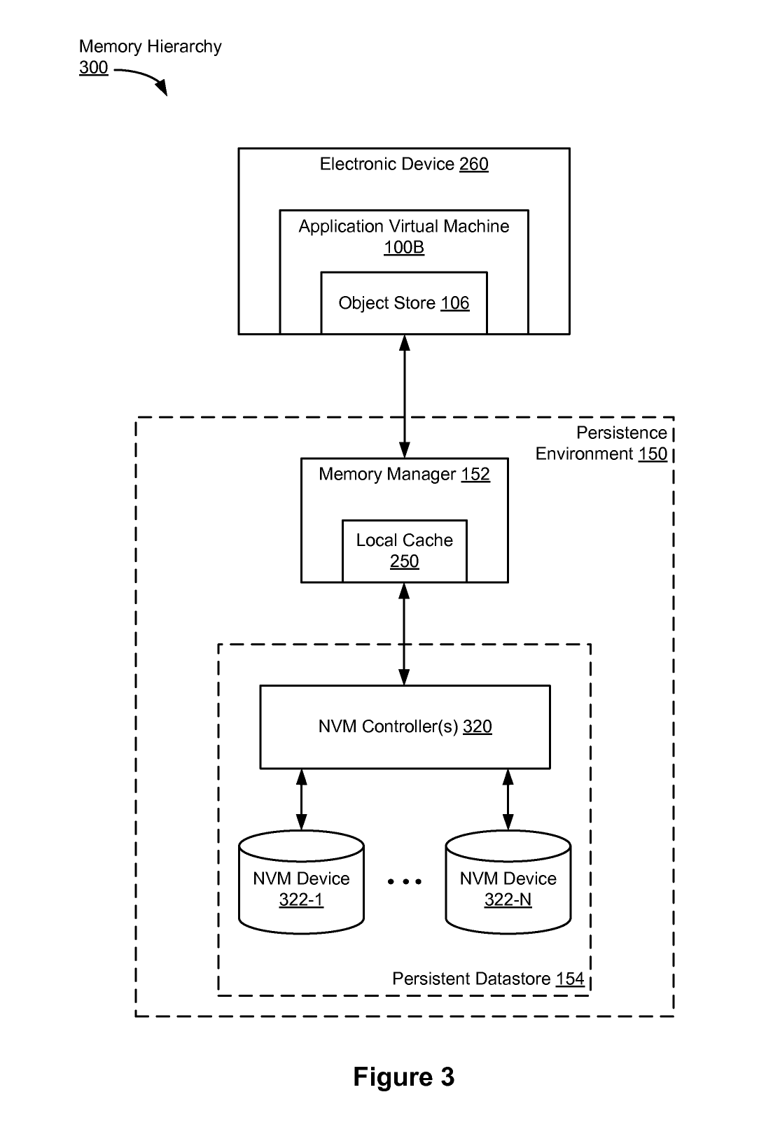

FIG. 3 is a block diagram illustrating an implementation of a memory hierarchy 300 in accordance with some embodiments. In some embodiments, persistent datastore 154, comprising one or more non-volatile memory devices 322, extends object store 106 corresponding to application virtual machine 100B. For example, objects move between object store 106 and persistent datastore 154.

In some embodiments, electronic device 260 (e.g., a client device or server system) executes or hosts application virtual machine 100B. In turn, objects associated with the application or program being run by application virtual machine 100B are instantiated in object store 106. In some embodiments, a migration engine in application virtual machine 100B (e.g., migration thread 124, FIG. 1B) selects objects in object store 106 for migration based on a migration/eviction process. In some embodiments, in order to migrate a selected object, the migration engine sends a request (e.g., a JNI put call) to memory manager 152 to migrate the selected object from object store 106 to persistent datastore 154.

In some embodiments, in response to receiving the request to migrate a respective object, memory manager 152 stores the respective object or copy thereof in local cache 250 and, subsequently, writes the respective object or copy thereof to persistent datastore 154. For example, the respective object or copy thereof is evicted from local cache 250 and written to persistent datastore 154 in accordance with a FIFO, LRU, or other well-known cache eviction policy.

In some embodiments, in order to retrieve an object, the migration engine sends a request (e.g., a JNI get call) to memory manager 152 to retrieve the object from persistent datastore 154 to object store 106. For example, when the application requires or references a migrated object. In some embodiments, in response to receiving the request to retrieve the object, memory manager 152 retrieves the object from persistent datastore 154 and makes the object available by storing the object or copy thereof in local cache 250. Subsequently, migration thread 124 or memory manager 152 writes the object or copy thereof to object store 106.

In some embodiments, persistent datastore 154 includes one or more non-volatile memory controllers 320 and one or more non-volatile memory devices 322. In some embodiments, one or more non-volatile memory devices 322 includes magnetic disk storage device(s), optical disk storage device(s), flash memory device(s), or other non-volatile solid state storage device(s). For example, one or more non-volatile memory controllers 320 handle requests to write to and read from non-volatile memory and monitor one or more non-volatile memory devices 322. In some embodiments, one or more non-volatile memory devices 322 include one or more three-dimensional (3D) memory devices, as further defined herein, or flash DIMMs. In some embodiments, the 3D memory devices are coupled to a controller (e.g., one or more non-volatile memory controllers 320). Further, in some embodiments, one or more non-volatile memory controllers 320 are solid-state drive (SSD) controllers. However, in some circumstances, one or more other types of semiconductor memory devices may be included in persistent datastore 154 in accordance with aspects of a wide variety of embodiments.

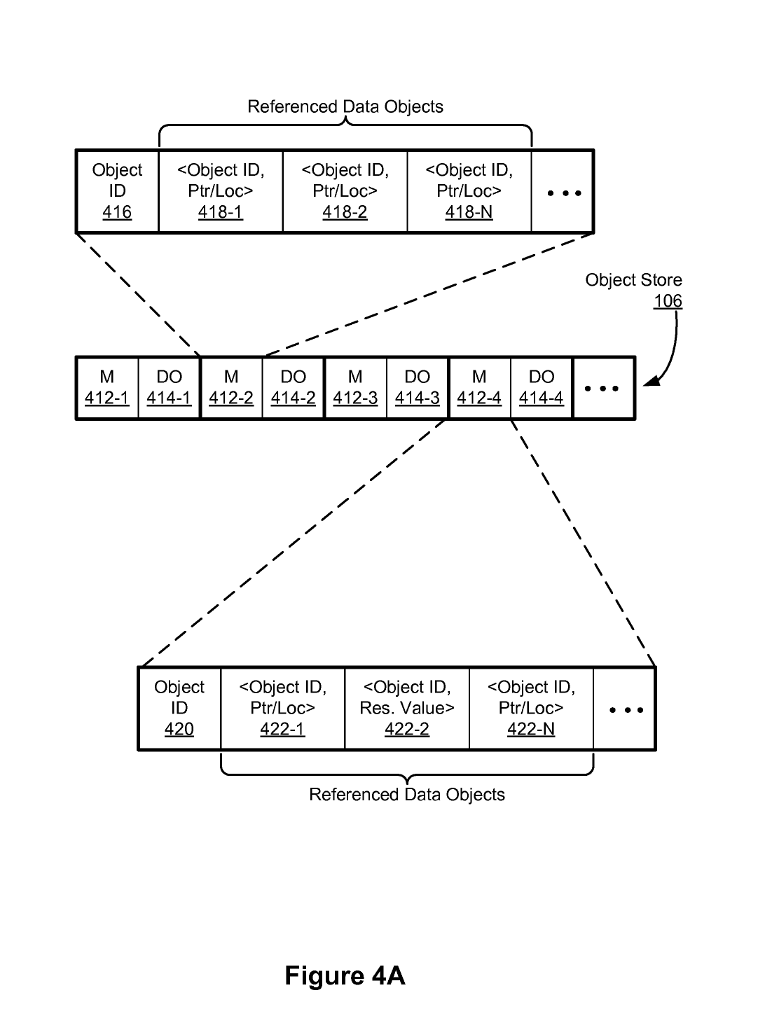

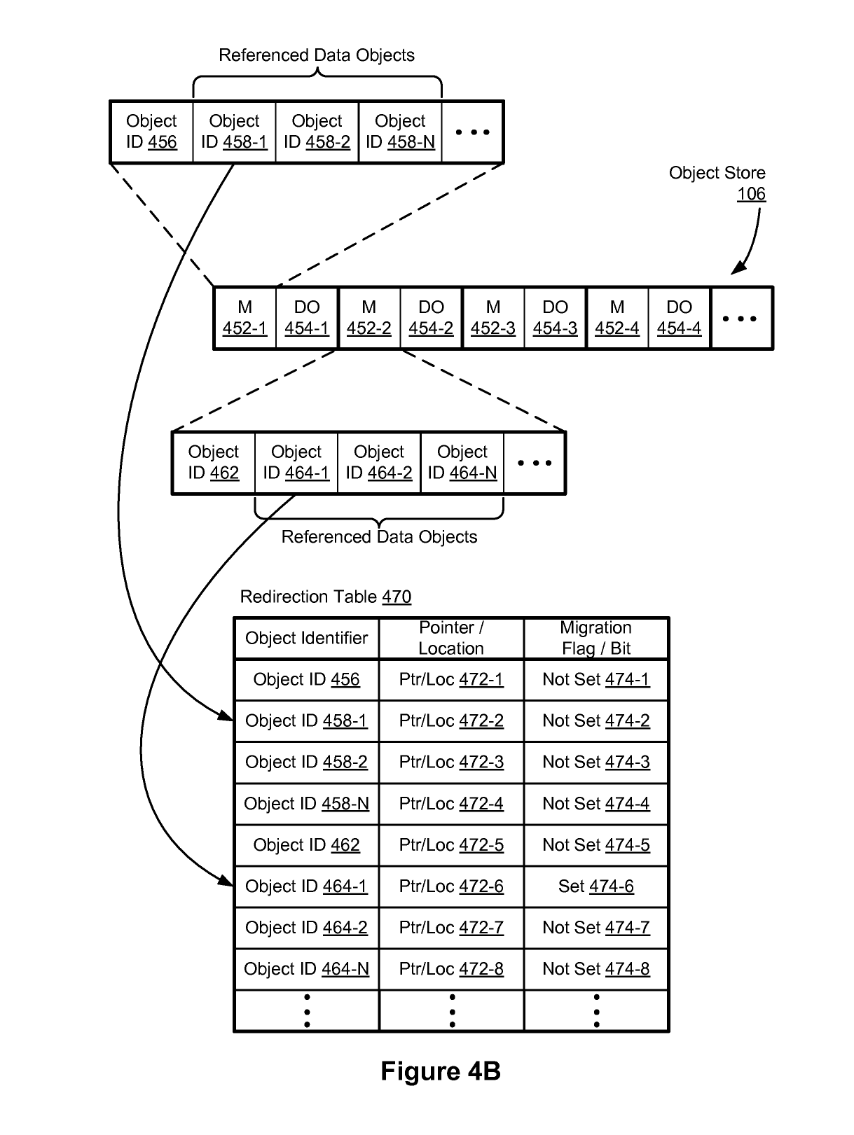

FIG. 4A is an implementation of a data structure associated with application virtual machine 100B in accordance with some embodiments. In FIG. 4A, a plurality of data objects 414 are stored in object store 106 corresponding to application virtual machine 100B (FIG. 1B). Each of data objects 414 is associated with corresponding metadata 412.

In FIG. 4A, metadata 412-2, which corresponds to data object 414-2, includes object identifier (“ID”) 416 for data object 414-2, a plurality of entries 418 that correspond to data objects referenced by data object 414-2, and other such metadata. Each of the plurality of entries 418 includes the object identifier of the referenced object and a pointer to the location of, or location of, the referenced object. In some embodiments, object identifier 416 for data object 414-2 is included in data object 414-2 and not in metadata 412-2.

In some embodiments, in accordance with a determination that a respective data object is to be migrated from object store 106 to persistent datastore 154 or after migrating the respective object to persistent datastore 154, migration thread 124 (FIG. 1B) is configured to set all metadata entries corresponding to the respective data object in data objects referencing the respective data object to a reserved value to indicate that the respective data object has been migrated to persistent datastore 154.

In FIG. 4A, metadata 412-4, which corresponds to data object 414-4, includes entry 422-2 to a data object referenced by data object 414-4. Entry 422-2 includes the object identifier of the referenced object and a reserved value indicating that the referenced data object has been migrated to persistent datastore 154.

FIG. 4B is an implementation of data structures associated with application virtual machine 100B in accordance with some embodiments. In FIG. 4B, a plurality of data objects 454 are stored in object store 106 corresponding to application virtual machine 100B (FIG. 1B). In FIG. 4B, each of data objects 454 is associated with corresponding metadata 452.

In FIG. 4B, metadata 452-1, which corresponds to data object 454-1, includes object identifier (“ID”) 456 for data object 454-1, a plurality object identifiers 458 to data objects referenced by data object 454-1, and other such metadata. In some embodiments, object identifier 456 for data object 454-1 is included in data object 454-1 and not in metadata 452-1. Similarly, metadata 452-2, which corresponds to data object 454-2, includes object identifier (“ID”) 462 for data object 454-2, a plurality object identifiers 464 to data objects referenced by data object 454-2, and other such metadata.

In FIG. 4B, redirection table 470 is associated with application virtual machine 100B and corresponds to the plurality of data objects 454 stored in object store 106. In FIG. 4B, each entry in redirection table 470 corresponds to a respective data object instantiated by application virtual machine 100B. In FIG. 4B, a respective entry in redirection table 470 includes the object identifier corresponding to the respective data object, a pointer 472 to the location of, or location of, the respective data object, and a migration flag or bit 474 indicating whether the respective data object exists in object store 106 or has been migrated to persistent datastore 154.

In some embodiments, in accordance with a determination that a respective data object is to be migrated from object store 106 to persistent datastore 154 or after migrating the respective object to persistent datastore 154, migration thread 124 (FIG. 1B) is configured to set the migration flag or bit 474 in redirection table 470 that corresponds to the respective data object to indicate that the respective data object has been migrated to persistent datastore 154.

For example, migration flag or bit 474-2 for the data object corresponding to object identifier 458-1, which is referenced by data object 454-1, is not set, indicating that the data object corresponding to object identifier 458-1 exists in object store 106. In another example, migration flag or bit 474-6 for the data object corresponding to object identifier 464-1, which is referenced by data object 454-2, is set, indicating that the data object corresponding to object identifier 464-1 has been migrated to persistent datastore 154.

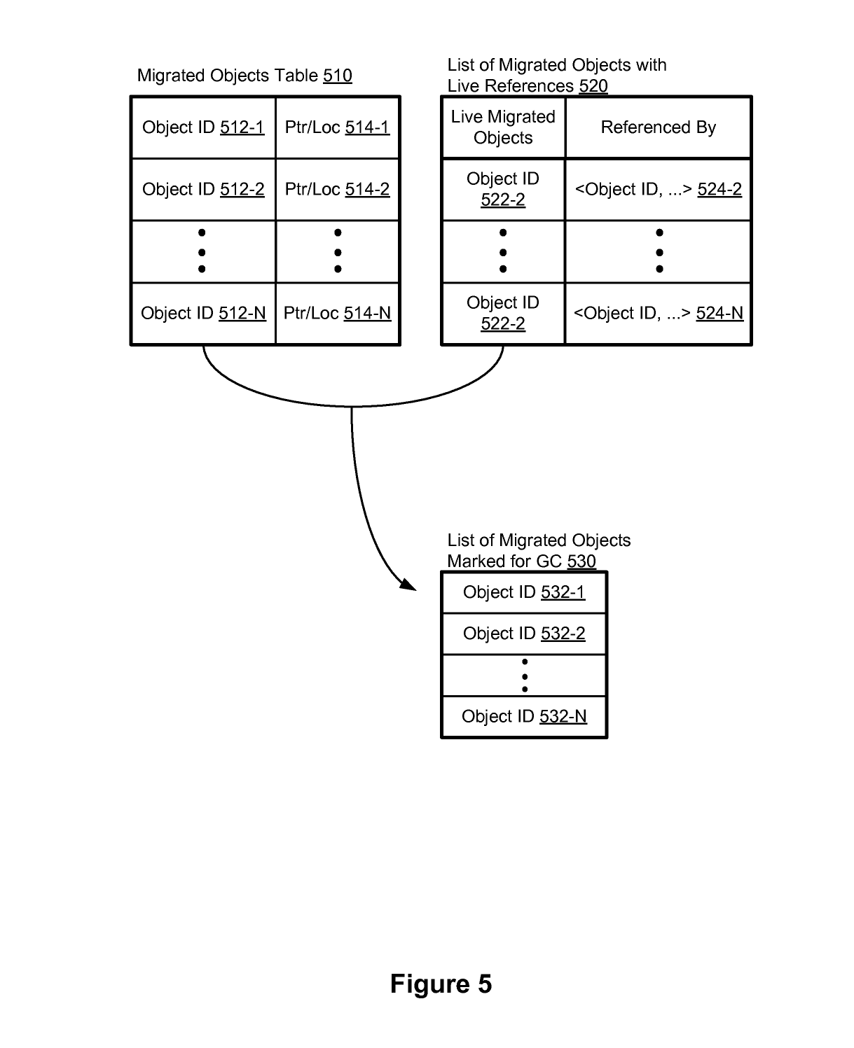

FIG. 5 illustrates data structures associated with an implementation of a garbage collection process for application virtual machine 100B in accordance with some embodiments. In some embodiments, migration thread 124 (FIG. 1B) maintains migrated objects table 510 and a list of migrated objects with live references 520.

In some embodiments, after causing a respective object to be migrated to persistent datastore 154, migration thread 124 creates an entry in migrated objects table 510 that corresponds to the respective object. In FIG. 5, migrated objects table 510 includes a plurality of entries, where each entry corresponds to a migrated object. A respective entry in migrated objects table 510 includes an object identifier (“ID”) 512 corresponding to the migrated object and, optionally, a pointer 514 to the location of, or the location of, the migrated object.

In some embodiments, list of migrated objects with live references 520 includes an entry for each migrated object that is referenced by objects in object store 106. A respective entry in the list of migrated objects with live references 520 includes an object identifier (“ID”) 522 corresponding to a respective migrated object and one or more object identifiers 524 corresponding to objects in object store 106 that reference the respective migrated object.

In some embodiments, after migrating a respective object, migration thread 124 scans the objects in object store 106 to create an entry in the list of migrated objects with live references 520 that corresponds to the respective object. In some embodiments, migration thread 124 periodically scans the objects in object store 106 to update entries in the list of migrated objects with live references 520. For example, if an object in object store 106 no longer references the respective migrated object, migration thread 124 updates the entry in the list of migrated objects with live references 520 that is associated with the respective migrated object to reflect this change. In another example, if the respective migrated object is no longer referenced by any objects in object store 106, migration thread 124 deletes the entry associated with the respective migrated object from the list of migrated objects with live references 520.

Alternatively, in some embodiments, during the garbage collection process, garbage collector thread 122 (FIG. 1B) scans objects in object store 106 to identify references in the objects in object store 106 to migrated objects in persistent datastore 154. In some embodiments, garbage collector thread 122 determines a list of migrated objects with live references 520 based on the identified references to migrated objects in persistent datastore 154.

In some embodiments, garbage collector thread 122 determines migrated objects to be garbage collected by performing a difference operation between migrated objects in migrated objects table 510 and live migrated objects in the list of migrated objects with live references 520. In some embodiments, migrated objects included in migrated objects table 510 but not included in the list of migrated objects with live references 520 are included in a list of migrated objects for garbage collection 530 that includes object identifiers 532 corresponding to such objects. In some embodiments, garbage collector thread 122 sends a request to memory manager 152 to garbage collect or delete objects in persistent datastore 154 that are included on the list of migrated objects for garbage collection 530.

FIGS. 6A-6C illustrate a flowchart representation of a method 600 of managing objects associated with an application virtual machine in accordance with some embodiments. In some embodiments, method 600 is performed by an application virtual machine being executed on an electronic device with one or more processors and memory of such as a server system (e.g., an application server) or client device (e.g., a mobile phone, laptop computer, desktop computer, tablet computer, wearable computing device, or other computing device). In some embodiments, method 600 is governed by instructions that are stored in a non-transitory computer readable storage medium and the instructions are executed by one or more processors of the electronic device executing or hosting the application virtual machine.

In some embodiments, application virtual machine 100B (FIG. 1B) is executed or hosted by electronic device 260 (FIG. 2B) which includes one or more processors and memory. A region of memory 266 (e.g., DRAM) is allocated for use by application virtual machine 100B. In some embodiments, the region of memory allocated for application virtual machine 100B comprises runtime data areas 104 (FIG. 1B) that includes object store 106. In some embodiments, electronic device 260 is operatively coupled with persistence environment 150 comprising memory manager 152 and persistent datastore 154 (e.g., including one or more non-volatile memory (“NVM”) devices such as flash memory devices).

The application virtual machine identifies (602) a subset of one or more migratable objects from among a plurality of objects associated with the application virtual machine, where the plurality of objects are stored in an object store comprising a portion of the region of memory allocated for the application virtual machine. In some embodiments, objects instantiated by application virtual machine 100B (FIG. 1B) are stored in object store 106. In some embodiments, migration thread 124 (FIG. 1B) identifies a subset of migratable objects from among the plurality of objects stored in object store 106.

In some embodiments, identifying the subset of migratable objects includes (604) identifying objects from the plurality of objects in the object store in accordance with one or more predefined criteria. In some embodiments, migration thread 124 identifies objects in object store 106 that are serializable as migratable objects. For example, an object is serializable when it is of a machine-independent form that allows the object to be stored in external storage. In some embodiments, migration thread 124 identifies objects in object store 106 that belong to a class that implements a predetermined interface, such as a migratable interface, as migratable objects. For example, the migratable interface is an empty interface (i.e., the migratable interface includes no extra methods) that serves as a marker or extension indicating that objects associated with classes that implement the migratable interface are migratable. In this example, the source code of the application/program is modified so that some classes implement the migratable interface. In some embodiments, migration thread 124 identifies objects in object store 106 that have or are associated with one or more attributes included in environment variables that are passed to application virtual machine 100B at start-up so as to be maximally transparent to the application or program. For example, one of the attributes is a size attribute specifying that only objects that are at least a predefined size are migratable.

In some embodiments, identifying the subset of migratable objects includes (606) identifying objects from the plurality of objects in the object store that are associated with (e.g., are instances of objects in) one or more specified classes. In some embodiments, environment variables are passed to application virtual machine 100B at start-up which identify classes that are migratable so to be maximally transparent to the application or program. For example, predefined core classes, such as the HashMap class, are identified as migratable at start-up.

In some embodiments, the application virtual machine determines (608) whether one or more predetermined conditions are satisfied. In some embodiments, one of the one or more conditions is satisfied when object store 106 contains a predetermined amount of unallocated or free space. For example, the condition is satisfied when object store 106 contains no free space or 25%, 50%, etc. of the total size of object store 106 is free or unallocated.

The application virtual machine selects (610) a respective object from the subset of migratable objects to be migrated from the object store to persistent datastore. In some embodiments, migration thread 124 is a daemon thread that selects the respective object for migration in accordance with a background migration/eviction process.

In some embodiments, the application virtual machine selects the respective object in accordance with a determination that the one or more predetermined conditions are satisfied. For example, migration thread 124 selects objects for migration when the one or more predetermined criteria are satisfied (e.g., object store 106 is full, 75% occupied, 50% occupied, etc.). Alternatively, in some embodiments, migratable objects that are untouched for a certain amount of time are migrated out of object store 106 to persistent datastore 154. In some embodiments, one or more objects in certain object classes determined to be candidates are automatically migrated from object store 106 to persistent datastore 154 before space becomes a concern. For example, specific classes with objects that are infrequently referenced and relatively large are automatically migrated to persistent datastore 154 to make room in object store 106 for more frequently referenced objects.

In some embodiments, the application virtual machine selects (612) the respective object to be migrated based at least in part on a predetermined replacement algorithm. In some embodiments, migration thread 124 selects the respective object for migration in accordance with a migration/eviction process or replacement algorithm. In some embodiments, the replacement algorithm is one of a plurality of well-known cache algorithms or cache eviction policies such as FIFO, LRU, clock replacement, random replacement, and the like. In some embodiments, objects are only migrated to persistent datastore 154 when they are determined to be victims of the replacement algorithm.

The application virtual machine causes (614) the respective object to be migrated from the object store to the persistent datastore. In some embodiments, migration thread 124 causes the respective object to be migrated by sending a request (e.g., a JNI put call) to memory manager 152 to migrate the selected object from object store 106 to persistent datastore 154 (e.g., comprising one or more non-volatile memory (“NVM”) devices 322, FIG. 3). In some embodiments, one or more non-volatile memory devices 322 comprising persistent datastore 154 include one or more three-dimensional (3D) memory devices, as further defined herein. In some embodiments, the 3D memory devices are coupled to a controller (e.g., one or more non-volatile memory controllers 320).

In some embodiments, as part of the migration process, the application virtual machine sends (616) a request to a memory manager associated with the persistent datastore to migrate the respective object. In some embodiments, the request is a JNI put call that is handled by memory manager 152. In some embodiments, memory manager 152 includes migration interface 224 (FIG. 2A) with CRUD operations for handling requests from application virtual machine 100B and also for managing objects stored in persistent datastore 154.

In some embodiments, as part of the migration process, the application virtual machine causes (618) the respective object to be stored in a memory corresponding to a memory manager associated with the persistent datastore prior to storing the respective object in the persistent datastore. In some embodiments, in response to the request from migration thread 124 to migrate a respective object, memory manager 152 stores the respective object or a copy thereof in local cache 250 prior to storing the copy of the respective object in persistent datastore 154. For example, memory manager 152 evicts the respective object or copy thereof from local cache 250 and writes it to persistent datastore 154 in accordance with a FIFO, LRU, or other well-known cache eviction policy.

In some embodiments, as part of the migration process, the application virtual machine generates (620) a stub in the object store that corresponds to the respective object. For example, migration thread 124 replaces the respective object with a stub in object store 106 which indicates that the respective object has been migrated to persistent datastore 154.

In some embodiments, as part of the migration process, the application virtual machine sets (622) a migration bit in an entry associated with the respective object in a redirection table. In some embodiments, in accordance with a determination that a respective data object is to be migrated from object store 106 to persistent datastore 154 or after migrating the respective object to persistent datastore 154, migration thread 124 is configured to set a migration flag or bit 474 in redirection table 470 that corresponds to the respective data object to indicate that the respective data object has been migrated to persistent datastore 154. In FIG. 4B, for example, migration flag or bit 474-6 has been set for the data object corresponding to object identifier 464-1 to indicate that the data object corresponding to object identifier 464-1 has been migrated to persistent datastore 154.

In some embodiments, as part of the migration process, the application virtual machine replace (625) references to the respective object with a reserved value indicating that the respective object has been migrated. In some embodiments, in accordance with a determination that a respective data object is to be migrated from object store 106 to persistent datastore 154 or after migrating the respective object to persistent datastore 154, migration thread 124 is configured to set all metadata entries corresponding to the respective data object in data objects referencing the respective data object to a reserved value to indicate that the respective data object has been migrated to persistent datastore 154. In FIG. 4A, for example, in metadata 412-4 corresponding to data object 414-4, entry 422-2 corresponding to a data object referenced by data object 414-4 is set to a reserved value indicating that the referenced data object has been migrated to persistent datastore 154.

In some embodiments, as part of the migration process, after setting the migration flag or bit associated with the respective object or replacing references to the respective object with a reserved value, the application virtual machine deletes (624/626) the respective object from the object store. In some embodiments, deleting the respective object includes marking the respective object for garbage collection and reclamation by garbage collector thread 122 (FIG. 1B).

In some embodiments, after causing the respective object to be migrated, the application virtual machine performs (627) a garbage collection process. In some embodiments, the garbage collection process is performed by garbage collector thread 122 (FIG. 1B). In some embodiments, the garbage collection process includes scanning the objects in object store 106 to identify a set of zero or more objects which are not referred to by live references in other objects. The set of zero or more identified objects are marked for garbage collection and, subsequently, the marked objects are deleted and their corresponding memory location(s) in object store 106 are reclaimed.

In some embodiments, after being migrated to the persistent datastore, the respective object does not refer (628) to any objects in the object store. In some embodiments, migratable objects must be serializable. The serializable objects are migrated to persistent datastore 154 with other objects that they refer to. As such, migrated objects in persistent datastore 154 do not have outbound references to objects in object store 106, and migrated objects may either be referred to, or pointed to, by objects in object store 106 or refer to other objects in persistent datastore 154.

In some embodiments, as part of the garbage collection process, the application virtual machine (630): determines a set of migrated objects in the persistent datastore that are referenced by live references in live objects in the object store; compares the determined set of migrated objects against a map of migrated objects to identify a set of migrated objects that are not referenced by live references in live objects in the object store; and marks the identified set of migrated objects for garbage collection. In some embodiments, migration thread 124 manages migrated objects table 510 (FIG. 5). For example, after causing a respective object to be migrated to persistent datastore 154, migration thread 124 creates an entry in migrated objects table 510 that corresponds to the respective object. In some embodiments, during the garbage collection process, garbage collector thread 122 scans objects in object store 106 to identify references in the objects in object store to migrated objects in persistent datastore 154. In some embodiments, garbage collector thread 122 determines a list of migrated objects with live references 520 based on the identified references to migrated objects in persistent datastore 154. In some embodiments, during the garbage collection process, garbage collector thread 122 performs a difference operation comparing the list of migrated objects with live references 520 to migrated objects table 510 to identify a set of migrated objects that are not referenced by live references in live objects in object store 106. The identified set of migrated objects are marked for garbage collection and included in a list of migrated objects for garbage collection 530. For example, the identified set of migrated objects are marked for garbage collection at some time in the future.

Alternatively, in some embodiments, garbage collector thread 122 defers garbage collection of migrated objects in persistent datastore 154. Instead, memory manager 152 or a component thereof (e.g., garbage collection module 244, FIG. 2A) performs a garbage collection process on migrated objects in persistent datastore 154 in parallel with a garbage collection process performed by garbage collector thread 122 on objects in object store 106.

In some embodiments, as part of the garbage collection process, the application virtual machine determines (632) a set of migrated objects in the persistent datastore that are referenced by live references in live objects, the live objects including live objects in the object store and live objects in the persistent datastore. In some embodiments, during the garbage collection process, garbage collector thread 122 determines a set of migrated objects that are referenced by live references (e.g., references to objects that have not been garbage collected) in live objects in object store 106 and/or persistent datastore 154.

In some embodiments, determining the set of migrated objects includes (634) retrieving from the persistent datastore object data, the object data comprising copies of objects or portions of live objects referenced by live references in other live objects. In some embodiments, garbage collector thread 122 sends a request (e.g., a JNI get call) to memory manager 152 to retrieve object data, including copies of migrated objects in persistent datastore 154 or portions of migrated objects in persistent datastore 154 that are referenced by live objects.

In some embodiments, retrieving the object data includes (636) storing the object data in a respective memory or memory portion distinct from the object store. In some embodiments, the object data (e.g., copies of migrated objects or portions of migrated objects in persistent datastore 154) is stored in a portion of object store 106 separate from the portion of object store 106 storing live non-migrated objects. As such, frequently used or “hot” objects existing in object store 106 are not displaced by the retrieved object data.

In some embodiments, determining the set of migrated objects also includes (638) identifying in the retrieved object data references to live objects in the object store and/or in the persistent datastore. In some embodiments, during the garbage collection process, garbage collector thread 122 identifies references in the retrieved object data to live objects in object store 106 and/or persistent datastore 154, and uses that information to populate the list of migrated objects with live references 520 (FIG. 5).

In some embodiments, as part of the garbage collection process, after determining the set of migrated objects (632), the application virtual machine compares (640) the determined set of migrated objects against a map of migrated objects to identify migrated objects that are not referenced by live references in live objects in the object store. In some embodiments, during the garbage collection process, garbage collector thread 122 performs a difference operation comparing the list of migrated objects with live references 520 to migrated objects table 510 to identify a set of migrated objects that are not referenced by live references in live objects in object store 106. The identified set of migrated objects are marked for garbage collection and included in a list of migrated objects for garbage collection 530. For example, the identified set of migrated objects are marked for garbage collection at some time in the future.

In some embodiments, prior to termination of the application virtual machine, the application virtual machine causes (642) migratable objects in the object store not currently stored in the persistent datastore to be migrated to the persistent datastore, and, after termination of the application virtual machine, a subsequent instance of the application virtual machine causes at least a subset of the migrated objects to be retrieved from the persistent datastore and stored in an object store of the subsequent instance of the application virtual machine. In some embodiments, prior to termination of application virtual machine 100B, migration thread 124 causes migratable objects that were not selected by the migration/eviction process to be migrated to persistent datastore 154. In some embodiments, memory manager 152 or a component thereof (e.g., persistence module 240, FIG. 2A) persists objects between instances of application virtual machine 100B by associating migrated objects with the application or program. In some embodiments, in a subsequent instance of application virtual machine 100B, migration thread 124 sends a request (e.g., a JNI get call) to retrieve persisted objects from the previous instance of application virtual machine 100B and stores the persisted objects from the previous instance of application virtual machine 100B in object store 106.

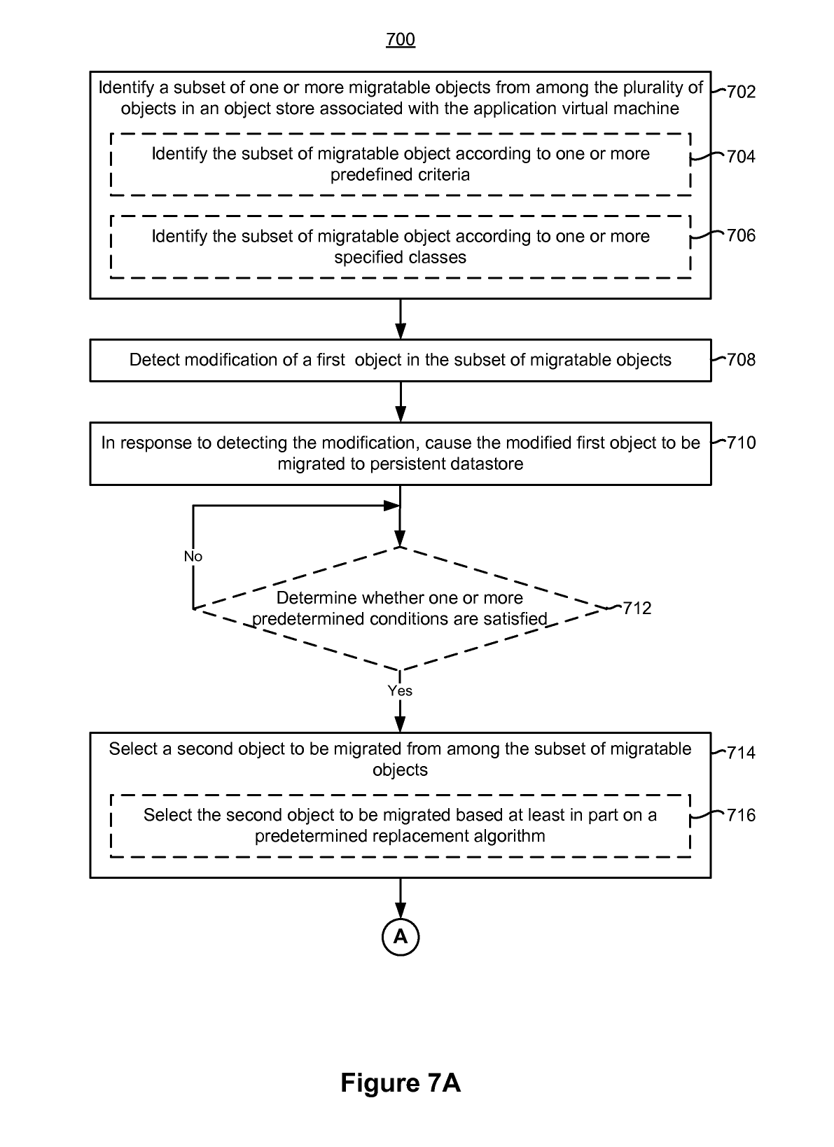

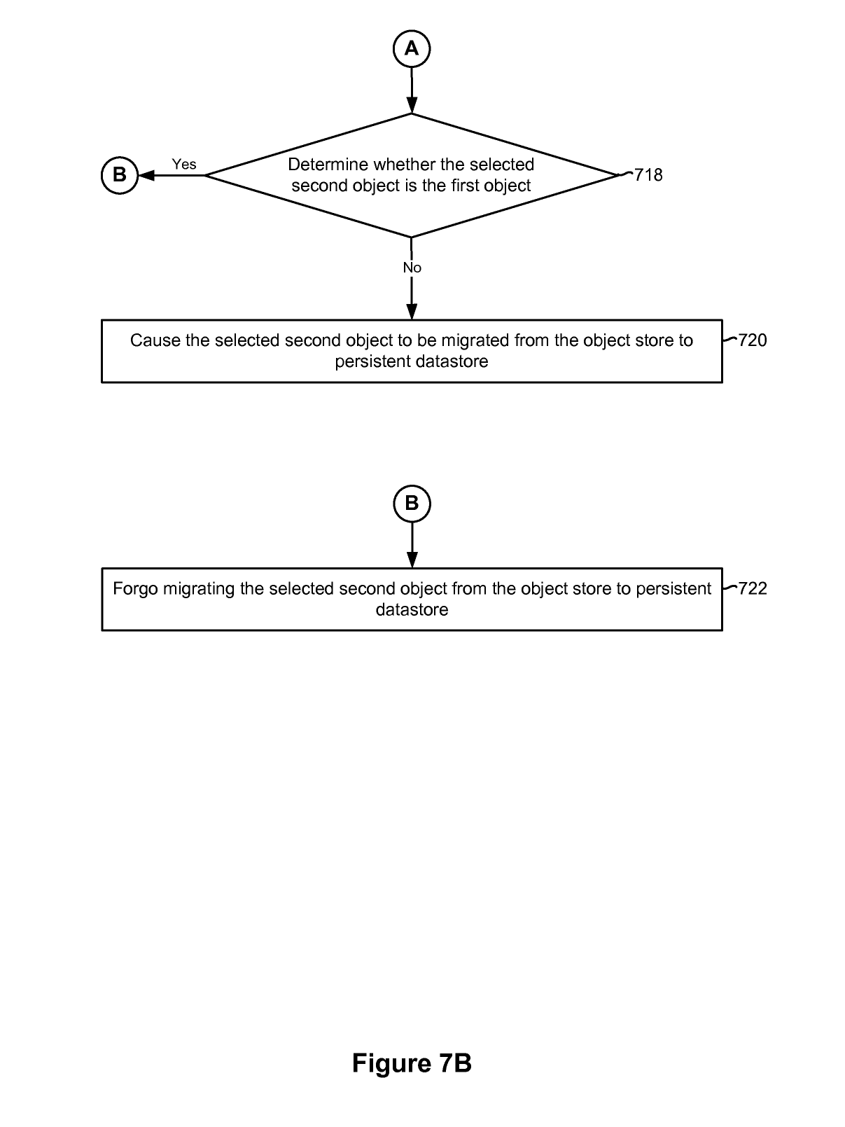

FIGS. 7A-7B illustrate a flowchart representation of a method 700 of managing objects associated with an application virtual machine in accordance with some embodiments. In some embodiments, method 700 is performed by an application virtual machine being executed on an electronic device with one or more processors and memory of such as a server system (e.g., an application server) or client device (e.g., a mobile phone, laptop computer, desktop computer, tablet computer, wearable computing device, or other computing device). In some embodiments, method 700 is governed by instructions that are stored in a non-transitory computer readable storage medium and the instructions are executed by one or more processors of the electronic device executing or hosting the application virtual machine.

In some embodiments, application virtual machine 100B (FIG. 1B) is executed or hosted by electronic device 260 (FIG. 2B) which includes one or more processors and memory. A region of memory 266 is allocated for use by application virtual machine 100B. In some embodiments, the region of memory allocated for application virtual machine 100B comprises runtime data areas 104 (FIG. 1B) that includes object store 106. In some embodiments, electronic device 260 is operatively coupled with persistence environment 150 comprising memory manager 152 and persistent datastore 154 (e.g., including one or more non-volatile memory (“NVM”) devices such as flash memory devices).

The application virtual machine identifies (702) a subset of one or more migratable objects from among a plurality of objects associated with the application virtual machine, where the plurality of objects are stored in an object store comprising a portion of the region of memory allocated for the application virtual machine. In some embodiments, objects instantiated by application virtual machine 100B are stored in object store 106. In some embodiments, migration thread 124 identifies a subset of migratable objects from among the plurality of objects stored in object store 106.

In some embodiments, identifying the subset of migratable objects includes (704) identifying objects from the plurality of objects in the object store in accordance with one or more predefined criteria. In some embodiments, migration thread 124 identifies objects in object store 106 that are serializable as migratable objects. For example, an object is serializable when it is of a machine-independent form that allows the object to be stored in external storage. In some embodiments, migration thread 124 identifies objects in object store 106 that belong to a class that implements a predetermined interface, such as a migratable interface, as migratable objects. For example, the migratable interface is an empty interface (i.e., the migratable interface includes no extra methods) that serves as a marker or extension indicating that objects associated with classes that implement the migratable interface are migratable. In this example, the source code of the application/program is modified so that classes implement the migratable interface. In some embodiments, migration thread 124 identifies objects in object store 106 that are associated with one or more attributes included in environment variables that are passed to application virtual machine 100B at start-up so as to be maximally transparent to the application or program. For example, one of the attributes is a size attribute specifying that only object that are at least a predefined size are migratable.

In some embodiments, identifying the subset of migratable objects includes (706) identifying objects from the plurality of objects in the object store that are associated with one or more specified classes. In some embodiments, environment variables are passed to application virtual machine 100B at start-up which identify classes that are migratable so to be maximally transparent to the application or program. For example, predefined core classes, such as the HashMap class, are identified as migratable at start-up.

The application virtual machine detects (708) a modification to (or creation of) a first object in the subset of migratable objects. In some embodiments, in accordance with a write-through methodology, the migration thread 124 detects a modification to (or creation of) a first object in object store 106.

In response to detecting the modification, the application virtual machine causes (710) the modified (or created) first object to be migrated to the persistent datastore. In some embodiments, in accordance with the write-through methodology, migration thread 124 causes the modified (or created) first object or a copy thereof to be migrated or written to persistent datastore 154. However, in some embodiments, migration thread does not release space allocated for the first object in object store 106, until the first object is selected by the replacement algorithm. For example, migration thread 124 sends a request (e.g., a JNI put call) to memory manager 152 to migrate the modified first object to persistent datastore 154.

In some embodiments, the application virtual machine determines (712) whether one or more predetermined conditions are satisfied. In some embodiments, one of the one or more conditions is satisfied when object store 106 contains a predetermined amount of unallocated or free space. For example, the condition is satisfied when object store 106 contains no free space or 25%, 50%, etc. of the total size of object store 106 is free or unallocated.

The application virtual machine selects (714) a second object from the subset of migratable objects to be migrated from the object store to persistent datastore. In some embodiments, migration thread 124 is a daemon thread that selects the respective object for migration in accordance with a background migration/eviction process.

In some embodiments, the application virtual machine selects the second object in accordance with a determination that the one or more predetermined conditions are satisfied. For example, migration thread 124 selects the second object for migration when the one or more predetermined are satisfied (e.g., object store 106 is full, 75% occupied, 50% occupied, etc.).

In some embodiments, the application virtual machine selects (716) the second object to be migrated based at least in part on a predetermined replacement algorithm. In some embodiments, migration thread 124 selects the respective object for migration in accordance with a migration/eviction process or replacement algorithm. In some embodiments, the replacement algorithm is one of a plurality of well-known cache algorithms or cache eviction policies such as FIFO, LRU, clock replacement, random replacement, and the like. In some embodiments, objects are only migrated to persistent datastore 154 when they are determined to be victims of the replacement algorithm.

The application virtual machine determines (718) whether the selected second object is the first object. In some embodiments, migration thread 124 determines whether the selected second object is the modified (or created) first object, which was already migrated or written to persistent datastore 154 in step 710.

In accordance with a determination that the selected second object is not the modified (or created) first object, the application virtual machine causes (720) the second object to be migrated from the object store to the persistent datastore. In some embodiments, migration thread 124 causes the respective object to be migrated by sending a request (e.g., a JNI put call) to memory manager 152 to migrate the selected object from object store 106 to persistent datastore 154.

In accordance with a determination that the selected second object is the modified (or created) first object, the application virtual machine forgoes (722) migration of the second object. In some embodiments, when the selected second object is the modified (or created) first object, migration thread 124 forgoes migration of the selected second object because the modified first object was already migrated or written to persistent datastore 154 in step 710. Furthermore, in some embodiments, migration thread 125, releases the space allocated to the first object in object store 106. For example, application virtual machine 100B writes out each modification to an object as it occurs. As such, in this example, when such a modified object is selected as a victim, the modified object not need to be written to persistent datastore 154 because the value for the modified object in persistent datastore 154 would be current.

In some implementations, with respect to any of the methods described above, persistent datastore 154 comprises a single non-volatile memory (“NVM”) device (e.g., a flash memory device), while in other implementations, persistent datastore 154 includes a plurality of NVM devices (e.g., flash memory devices). In some implementations, with respect to any of the methods described above, the persistent datastore 154 comprises a storage controller (e.g., one or more NVM controller 320, FIG. 3) and a storage medium (e.g., one or more NVM devices 322, FIG. 3).

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible (e.g., a NOR memory array). NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration (e.g., in an x-z plane), resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device level. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

The term “three-dimensional memory device” (or 3D memory device) is herein defined to mean a memory device having multiple memory layers or multiple levels (e.g., sometimes called multiple memory device levels) of memory elements, including any of the following: a memory device having a monolithic or non-monolithic 3D memory array, some non-limiting examples of which are described above; or two or more 2D and/or 3D memory devices, packaged together to form a stacked-chip memory device, some non-limiting examples of which are described above.

One of skill in the art will recognize that this invention is not limited to the two dimensional and three dimensional exemplary structures described but cover all relevant memory structures within the spirit and scope of the invention as described herein and as understood by one of skill in the art.

It will be understood that, although the terms “first,” “second,” etc. may be used herein to describe various elements, these elements should not be limited by these terms. These terms are only used to distinguish one element from another. For example, a first object could be termed a second object, and, similarly, a second object could be termed a first object, without changing the meaning of the description, so long as all occurrences of the “first object” are renamed consistently and all occurrences of the “second object” are renamed consistently. The first object and the second object are both objects, but they are not the same object.

The terminology used herein is for the purpose of describing particular embodiments only and is not intended to be limiting of the claims. As used in the description of the embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the phrase “at least one of A, B and C” is to be construed to require one or more of the listed items, and this phase reads on a single instance of A alone, a single instance of B alone, or a single instance of C alone, while also encompassing combinations of the listed items such as “one or more of A and one or more of B without any of C,” and the like.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A method of managing objects associated with an application virtual machine executed by an electronic device with one or more processors and memory, the method comprising:
identifying a subset of migratable objects from a plurality of objects associated with the application virtual machine, wherein the subset of migratable objects includes one or more objects and the plurality of objects are stored in an object store comprising a portion of the memory allocated for the application virtual machine;
selecting a respective object from the subset of migratable objects to be migrated from the object store to a persistent datastore that is operatively coupled to the electronic device, wherein the persistent datastore is distinct from the memory associated with the electronic device; and
causing the respective object to be migrated from the object store to the persistent datastore.

2. The method of claim 1, further comprising:
prior to selecting the respective object, determining whether one or more predetermined conditions are satisfied; and
wherein the selecting includes selecting the respective object in accordance with a determination that the one or more predetermined conditions are satisfied.

3. The method of claim 1, wherein identifying the subset of migratable objects includes identifying objects from the plurality of objects in the object store in accordance with one or more predefined criteria.

4. The method of claim 1, wherein identifying the subset of migratable objects includes identifying objects from the plurality of objects in the object store that are associated with one or more specified classes.

5. The method of claim 1, wherein selecting the respective object to be migrated includes selecting the respective object to be migrated based at least in part on a predetermined replacement algorithm.

6. The method of claim 1, wherein causing the respective object to be migrated includes sending a request to a memory manager associated with the persistent datastore to migrate the respective object.

7. The method of claim 1, wherein causing the respective object to be migrated includes causing the respective object to be stored in memory associated with a memory manager associated with the persistent datastore prior to storing the respective object in the persistent datastore.

8. The method of claim 1, wherein causing the respective object to be migrated includes generating a stub in the object store for the respective object.

9. The method of claim 1, wherein causing the respective object to be migrated includes setting a migration bit in an entry associated with the respective object in a redirection table.

10. The method of claim 1, wherein causing the respective object to be migrated includes replacing references to the respective object with a reserved value indicating that the respective object has been migrated.

11. The method of claim 1, wherein, after being migrated to the persistent datastore, the respective object does not refer to any objects in the object store.

12. The method of claim 11, further including:
determining a set of migrated objects in the persistent datastore that are referenced by live references in live objects in the object store;
comparing the determined set of migrated objects against a map of migrated objects to identify a set of migrated objects that are not referenced by live references in live objects in the object store; and
marking the identified set of migrated objects for garbage collection.

13. The method of claim 1, further comprising:
determining a set of migrated objects in the persistent datastore that are referenced by live references in live objects, the live object including live objects in the object store and live objects in the persistent datastore;
comparing the determined set of migrated objects against a map of migrated objects to identify migrated objects that are not referenced by live references in live objects in the object store; and
marking the identified set of migrated objects for garbage collection;
wherein determining the set of migrated objects includes:
retrieving from the persistent datastore object data, the object data comprises copies of objects or portions of live objects referenced by live references in other live objects; and
identifying in the retrieved object data references to live objects in the object store and/or in the persistent datastore.

14. The method of claim 13, wherein retrieving the object data includes storing the object data in a respective memory or memory portion distinct from the object store.

15. The method of claim 1, further comprising:
prior to termination of the application virtual machine, causing migratable objects in the object store not currently stored in the persistent datastore to be migrated to the persistent datastore; and
after termination of the application virtual machine, causing at least a subset of the migrated objects to be retrieved from the persistent datastore and stored in an object store of a subsequent instance of the application virtual machine.

16. An electronic device, comprising:
one or more processors; and
memory storing one or more programs to be executed by the one or more processors, the one or more programs comprising instructions for:
identifying a subset of migratable objects from a plurality of objects associated with an application virtual machine hosted by the electronic device, wherein the subset of migratable objects includes one or more objects and the plurality of objects are stored in an object store comprising a portion of the memory allocated for the application virtual machine;
selecting a respective object from the subset of migratable objects to be migrated from the object store to a persistent datastore operatively coupled to the electronic device, wherein the persistent datastore is distinct from the memory associated with the electronic device; and
causing the respective object to be migrated from the object store to the persistent datastore.

17. The electronic device of claim 16, wherein identifying the subset of migratable objects includes identifying objects from the plurality of objects stored in the object store in accordance with one or more predefined criteria.

18. The electronic device of claim 16, wherein selecting the respective object to be migrated includes selecting the respective object to be migrated based at least in part on a predetermined replacement algorithm.

19. The electronic device of claim 16, wherein causing the respective object to be migrated includes one or more of:
sending a request to a memory manager associated with the persistent datastore to migrate the respective object;
causing the respective object to be stored in memory associated with a memory manager associated with the persistent datastore prior to storing the respective object in the persistent datastore;
generating a stub in the object store for the respective object;
setting a migration bit in an entry associated with the respective object in a redirection table; and
replacing references to the respective object with a reserved value indicating that the respective object has been migrated.

20. The electronic device of claim 16, wherein the one or more programs, when executed by the one or more processors, cause the electronic device to further perform:
determining a set of migrated objects in the persistent datastore that are referenced by live references in live objects in the object store;
comparing the determined set of migrated objects against a map of migrated objects to identify a set of migrated objects that are not referenced by live references in live objects in the object store; and
marking the identified set of migrated objects for garbage collection.

21. A non-transitory computer readable storage medium storing one or more programs, the one or more programs comprising instructions, which, when executed by an electronic system with one or more processors, cause the electronic system to perform operations comprising:
identifying a subset of migratable objects from a plurality of objects associated with an application virtual machine hosted by the electronic device, wherein the subset of migratable objects includes one or more objects and the plurality of objects are stored in an object store comprising a portion of the memory allocated for the application virtual machine;
selecting a respective object from the subset of migratable objects to be migrated from the object store to a persistent datastore operatively coupled to the electronic device, wherein the persistent datastore is distinct from the memory associated with the electronic device; and
causing the respective object to be migrated from the object store to the persistent datastore.

22. The non-transitory computer readable storage medium of claim 21, wherein identifying the subset of migratable objects includes identifying objects from the plurality of objects stored in the object store in accordance with one or more predefined criteria.

23. The non-transitory computer readable storage medium of claim 21, wherein causing the respective object to be migrated includes one or more of:
sending a request to a memory manager associated with the persistent datastore to migrate the respective object;
causing the respective object to be stored in memory associated with a memory manager associated with the persistent datastore prior to storing the respective object in the persistent datastore;
generating a stub in the object store for the respective object;
setting a migration bit in an entry associated with the respective object in a redirection table; and
replacing references to the respective object with a reserved value indicating that the respective object has been migrated.

24. The non-transitory computer readable storage medium of claim 21, wherein the one or more programs, when executed by the one or more processors, cause the electronic system to further perform:
determining a set of migrated objects in the persistent datastore that are referenced by live references in live objects in the object store;
comparing the determined set of migrated objects against a map of migrated objects to identify a set of migrated objects that are not referenced by live references in live objects in the object store; and
marking the identified set of migrated objects for garbage collection.
